(19) United States
(12) Patent Application Publication
(10) Pub. No.: US 2026/0061480 A1
(43) Pub. Date: Mar. 5, 2026

(54) WIRE BONDING TOOL

(71) Applicant: Infineon Technologies AG, Neubiberg (DE)

(72) Inventor: Oliver HAGEDORN, Paderborn (DE)

(73) Assignee: Infineon Technologies AG, Neubiberg (DE)

(21) Appl. No.: 19/288,327

(22) Filed: Aug. 1, 2025

(30) Foreign Application Priority Data
Aug. 2, 2024 (DE) 10 2024 122 196.8

(51) Int. Cl. B21F 7/00

(52) U.S. Cl. CPC B21F 7/00

(57) ABSTRACT

A wire bonding tool is disclosed. In one example, the wire bonding tool includes a groove for accommodating a bonding wire, and a pair of jaws defining side walls of the groove. Each jaw of the pair of jaws has a tip surface configured to face a bonding surface during operation. The tip surface of each jaw is curved.

### CROSS-REFERENCE TO RELATED APPLICATION

This Utility Patent Application claims priority to German Patent Application No. 10 2024 122 196.8 filed Aug. 2, 2024, which is incorporated herein by reference.

### TECHNICAL FIELD

Various embodiments relate generally to a wire bonding tool.

### BACKGROUND

Wire bonding tools as known in the art may be configured in a way that may lead to yield loss due to substrate damage (e.g. cratering, metal lift off, tool-substrate-contact, electrical fails).

Known solutions are reduced bond parameters, which may lead to lift off. Other solutions include more robust substrates, which may not always be a feasible solution in terms of producibility and costs.

### SUMMARY

A wire bonding tool is provided. The wire bonding tool includes a groove for accommodating a bonding wire, and a pair of jaws defining side walls of the groove, wherein each jaw of the pair of jaws has a tip surface configured to face a bonding surface during operation, and wherein the tip surface of each jaw is curved.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows two different schematic cross-sectional partial views FIGS. 1A, 1B of a wire bonding tool in accordance with various embodiments;

FIG. 2 shows a schematic bottom view FIG. 2A and two schematic partial cross-sectional views FIGS. 2B, 2C of a wire bonding tool in accordance with various embodiments; and

each of FIGS. 3A and 3B shows a schematic partial cross-sectional view of a wire bonding tool in accordance with various embodiments during operation.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Wire bonding tools of the prior art may cause involuntary damage and/or defective bonds during a wire bonding process. The damage may for example affect a bonding wire and/or a bonding surface to which the bonding wire is to be bonded and/or a substrate (e.g., a semiconductor substrate) that includes the bonding surface.

Damage may for example include kinks, dents and/or breaks in the bonding wire, dents and/or cracks in the substrate, and the bond may for example include an interface region with a contamination or a lack of contact.

In various embodiments, a wire bonding tool for reducing damage, for example for reducing a substrate damage and/or a bonding surface damage and/or a bonding wire damage is provided. In various embodiments, a quality of the bond may be improved.

The wire bonding tool may for example be configured as an ultrasonic or thermosonic wire bonding tool.

In various embodiments, a wire bonding tool (“bonding tool” for short) is provided that includes a groove for accomodating a bonding wire (“wire” for short), wherein the groove includes a customized groove geometry. The groove geometry may be adapted to a diameter and/or a material of the bonding wire, and may be configured to avoid damage to the bonding wire and/or to a bonding surface to which the bonding wire is bonded, and/or to a substrate underneath the bonding surface.

The customized groove geometry in accordance with various embodiments may include any, some, or all of the following features:

A groove for accomodating the bonding wire that is curved along its entire length (in other words, there is no flat portion along the length of the groove), which may ensure that the bond forms from a central portion outward, rather than forming from edges inward, thereby trapping contaminations between the bonding wire and the bonding surface. The curved groove of the wire bonding tool to initiate continuous growth of the contact length in bond direction may reduce mechanical stress in the heel and tail region of the bonding region, where the bond formation starts.

The curve of the groove may be defined as piecewise polynominal functions (“spline” for short) of at least second order, which may allow for an easy adaptability of the curve to limiting parameters.

The groove may be configured to provide a smooth transition from the groove to a shank of the wire bonding tool at front of the wire bonding tool. This may include that the groove (e.g., an apical line defined by a line of apices of all cross sections across a width of the groove), at its interface with a side surface of the shank, is tangential to the side surface of the shank. This may prevent damage to the bonding wire during loop formation. Otherwise, the spline can be constructed with an angle to the shank at the front.

The groove may be configured to provide a smooth transition from the groove to a wire guide at a back of the shank. This may reduce plastic strain of the bonding wire, especially at the heel region, before and/or during bonding. Otherwise the groove can be configured to provide a smooth transition from the groove to a shank of the wire bonding tool at the back of the wire bonding tool.

A shape of the groove across its width may be a conical section, for example a parabola, an ellipse, or a hyperbola (as opposed to a V-shaped groove that is common in the prior art). This may define a smooth shape that is easily adaptable to be varied from a near-circular shape to a near-V-shape, each of which may be preferred depending on, for example, a material of the bonding wire.

A foot of the wire bonding tool may be provided with a curved outline. The foot of the wire bonding tool may include jaws that define side walls of the groove. The jaws may include bottom surfaces, which are configured to face the bonding surface during the bonding process, which may be curved, for example along a length of each jaw (and optionally across a width of each jaw). This may reduce metallization damage and/or substrate damage in case of tool-substrate-contact during the bonding process.

A contact point, which may specify a point at which the apical line of the groove extends furthest towards the bonding surface, may be easily adjustable, for example in its position along the length of the groove. The spline definition of the groove may for example make such an adjustment easy. Such an adjustment may allow to easily reduce scooting (which refers to a sliding of the wire over the bonding surface in one direction when a foot point of the pressure force exerted by the wire bonding tool does not coincide with the contact point of the wire) by moving the contact point to a center of force transmission.

Experiments were conducted in which bonds were formed using bonding tools in accordance with various embodiments. The resulting bonds and bonding partners (bonding wire, bonding surface and substrate on which the bonding surface is formed) were analyzed.

The bonds formed using the bonding tools in accordance with the embodiments were determined, using simulations, to have higher shear values, a higher shear strength, a slightly higher bond grade (ratio of bonded area to contact area), a slightly higher homogenity of contact pressure, a reduced substrate damage, a smaller damaged area (heel and tail) on the bonding surface, a smaller unbonded area in a center of the bond, and a more homogeneous shear value over the contact area.

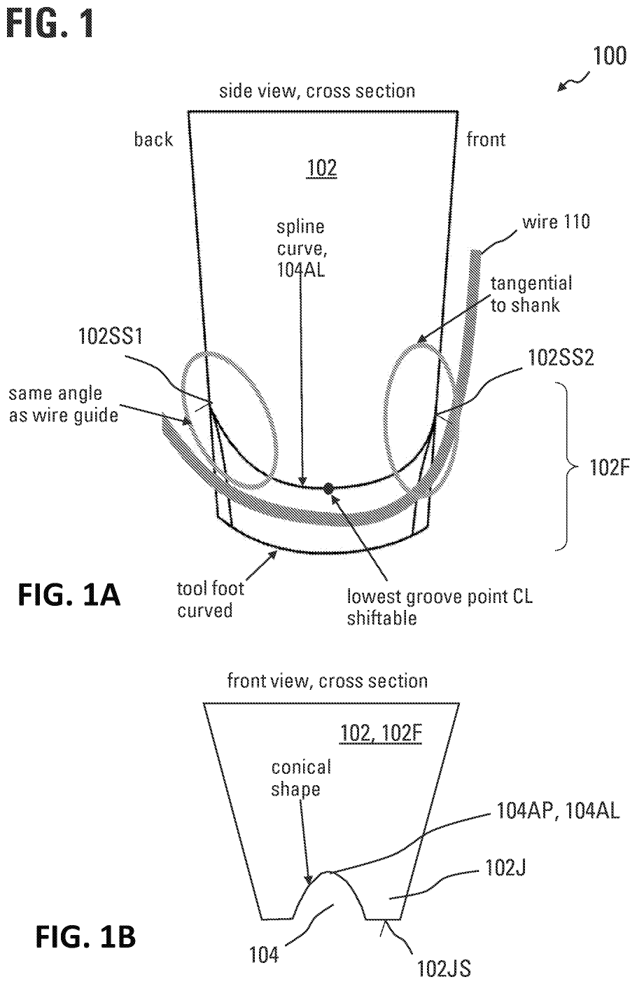

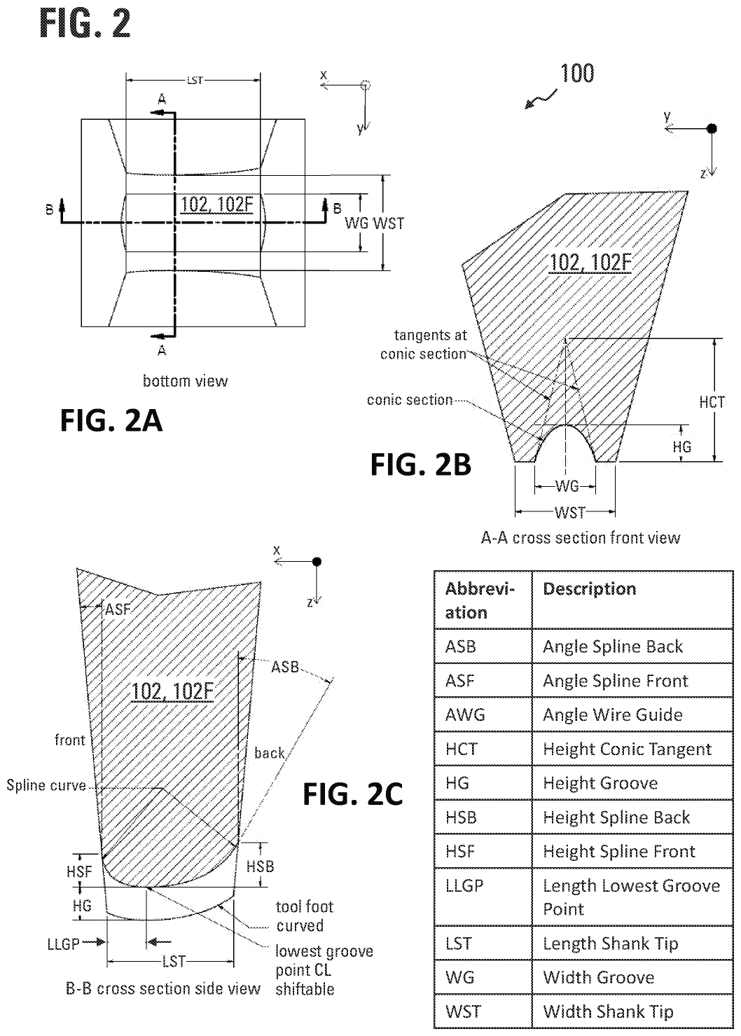

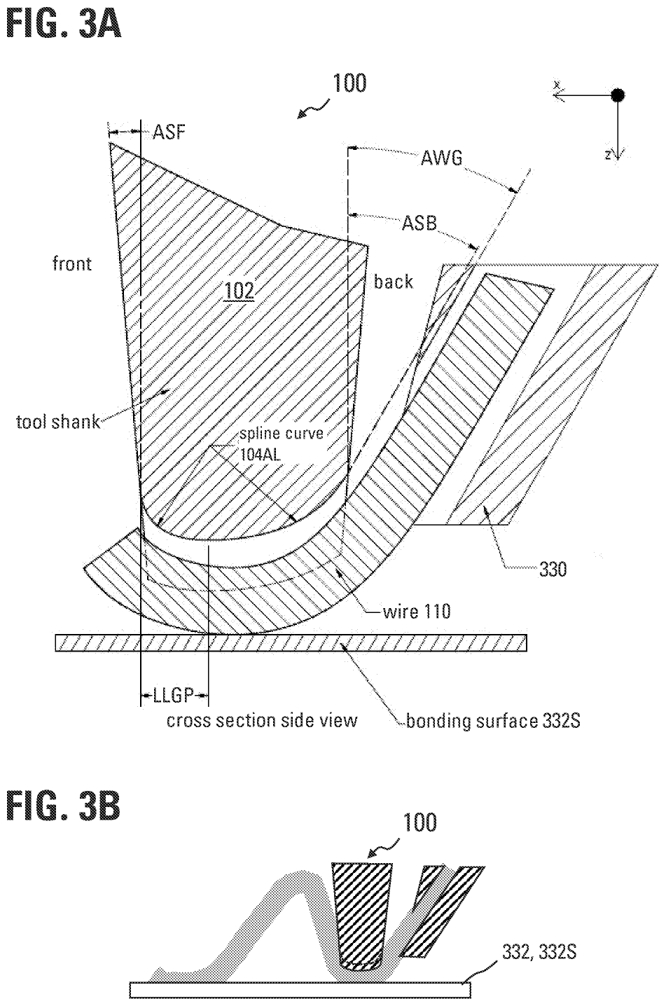

FIG. 1 shows two different schematic cross-sectional partial views FIGS. 1A, 1B of a wire bonding tool 100 in accordance with various embodiments; FIG. 2 shows a schematic bottom view FIG. 2A and two schematic partial cross-sectional views FIGS. 2B, 2C of a wire bonding tool 100 in accordance with various embodiments; and each of FIGS. 3A and 3B shows a schematic partial cross-sectional side view of a wire bonding tool 100 in accordance with various embodiments during operation.

In the following, various aspects of the wire bonding tool 100 in accordance with various embodiments will be described. Each of these aspects may provide an individual improvement to a quality of the bond, and thereby to a device, e.g., a semiconductor device, including the bond. Combining two or more of the aspects in the wire bonding tool 100 in accordance with various embodiments will lead to further improvement and/or to synergetic effects regarding the improvements.

The wire bonding tool 100 includes a groove 104 for accommodating a bonding wire 110, and a pair of jaws 102J defining side walls of the groove 104.

The groove 104 may be located at one end of a (longitudinally extended) shank 102. A portion of the shank 102 that includes the groove 104 and the jaws 102J may be referred to as foot 102F.

FIG. 3A shows that the wire bonding tool 100 may further include a wire feeder 330. The wire bonding tool 100 may be mounted to an ultrasonic transducer, which is part of a bond head (opposite the tip). To the bondhead, the wire feeder 330 and a cutting device for cutting the bonding wire 110 after finishing one or more bonding connection(s) may be mounted. The wire bonding tool 100 may further include other parts as known in the art.

Each jaw 102J of the pair of jaws 102J has a tip surface 102JS (in FIG. 3A, which shows the wire bonding tool 100 in operation, this is a bottom surface) configured to face a bonding surface 332S (e.g., on a substrate 332) during operation, and wherein the tip surface 102JS of each jaw 102J is curved.

Each of the jaws 102J may for example extend in a direction along the length of the groove 104. This may be referred to as the length direction or the longitudinal direction of the jaw. An orthogonal direction (e.g., across both jaws 102J and the groove 104) may be referred to as a width direction. The tip surface 102JS of each of the jaws 102J may be curved along the whole length direction of the jaw (the length of the jaws 102J is referred to als LST, for Length Shank Tip). In particular, transition regions between the tip surface 102JS of each jaw 102J and adjoining side surfaces of the jaw 102J may be smooth.

The tip surface 102JS of each jaw 102J may have a convex shape in the length direction of the jaw.

In addition, the tip surface 102JS of each jaw 102J may be curved, e.g., with a convex shape, in a width direction of the jaw. As an alternative, the tip surface 102S of each jaw 102J may be flat or concave. A width of the tip that includes both jaws 102J is referred to as WST, for Width Shank Tip.

In various embodiments, the curve of the tip surface 102JS of each jaw 102J may be defined as at least one spline.

The curved tip surface 102JS of the jaws 102J may make a damage on the bonding surface and/or a substrate underneath the bonding surface less likely in a case of involuntary contact between one or both jaws 102J and bonding surface.

In various embodiments, a wire bonding tool 100 is provided that includes a groove 104 for accommodating a bonding wire 110, wherein a shape of an apical line 104AL of the groove 104 is a continuous convex curve defined by at least one spline, for example one, two, or more splines. The curve of the groove 104 being convex is to be understood as the material of the tip of the shank 102 that defines the apical line of the groove 104 having a convex shape, which means that the void that forms the actual groove 104 has a corresponding concave shape. A spline may be a function defined piecewise by polynomials. The apical line 104AL may be defined by a line of apices of all cross sections across a width of the groove 104.

Defining the groove 104 geometry by one or more splines may be advantageous in that it may allow on the one hand a smooth curved geometry, and on the other hand allow to easily define and adjust the geometry according to predetermined parameters like an angle AWG under which the bonding wire 110 is fed to the groove 104, a position of a foot point of the bonding force applied to the bonding wire 110, etc.

In various embodiments, the wire bonding tool 100 may optionally further include a shank 102, wherein the groove 104 is formed at one end (also referred to as tip) of the shank 102.

The following features are best understood from FIGS. 3A and 3B, which show the wire bonding tool 100 during operation, in particular from the sketch of FIG. 3B, which shows two sequential bonds formed by the bonding tool 100.

The groove 104 may include a receiving end configured to receive the bonding wire 110, and a releasing end configured to release the bonding wire 110.

A depth and shape of the groove 104 may be configured to ensure that some fraction of the diameter of the wire 110, for example at least 40 % or approximately 50 %, is located outside the groove 104 during an operation of the wire bonding tool 100.

The fraction may be substantially below 100 %, for example less than 60 %.

In various embodiments, at the receiving end of the groove 104, an angle between a tangential to the apical line 104AL of the groove 104 and a surface 102SS1 of the shank 102 may form an acute angle ASB, for example an angle ASB of less than 15°, of less than 20°, of less than 25°, of less than 30°, of less than 35°, of less than 40°, or of less than 45°.

The acute angle ASB may be adjusted to a feeding angle AWG at which the bonding wire 110 is provided to the receiving end by a bonding wire feeder 330.

Thereby, a damage of the wire 110 at the receiving end during the feeding may be avoided. Best results may be expected for ASB=AWG.

At the releasing end, the apical line 104AL of the groove 104 may be tangential to an adjoining surface 102SS2 of the shank 102. Thereby, it may be avoided that the looping bonding wire 110 is damaged at an interface between the releasing end of the groove 104 and the shaft at a front side of the wire bonding tool 100 (see in particular FIG. 3B).

In various embodiments, the curve of the tip surface 102JS of each jaw 102J may be essentially parallel to the apical line 104AL of the groove 104.

In various embodiments, parameters defining the at least one spline may include at least one of a group of parameters, the group including or consisting of (see FIG. 2 for an illustration and a list of the parameters): a height HG of the groove 104 (also referred to as the depth of the groove 104) defined as a distance, in a cross section across a width of the groove 104 through a (longitudinal) center of the groove 104, between a tip surface 102JS of the jaws 102J and an apex of the groove 104, a receiving end height HSB defined as a distance between the apex point 104AP of the groove 104 at the receiving end and at the center of the groove 104, a releasing end height HSF defined as a distance between the apex point 104AP of the groove 104 at the releasing end and at the center of the groove 104, an angle ASB between a vertical and the apical line 104AL at the receiving end.

The receiving end height HSB may in various embodiments be equal to the releasing end height HSF.

In various embodiments, the receiving end height HSB may be different from the releasing end height HSF, wherein the receiving end height HSB may be larger than the releasing end height HSF, or the releasing end height HSF may be larger than the receiving end height HSB.

A contact portion of the bonding wire 110 with a bonding surface 332S, which may be the portion of the bonding wire 110 that is first to contact the bonding surface during the bonding process, may be located underneath an area of the foot portion where the apical line 104AL is closest to the bonding surface 332S.

In various embodiments, the apical line 104AL may be configured to position the contact portion underneath a foot portion of a force vector for applying a bonding force. In other words, a vector of the bonding force may point, e.g. vertically, towards the contact portion, which may optionally be positioned off of the longitudinal axis of the shaft or a geometrical center of the area of the foot. The above described adjustment may mean that a distance between an end of the groove (e.g., the releasing end) and the lowest point of the groove LLGP (for Length Lowest Groove Point) need not coincide with the center of the groove and/or the center of the foot. In particular, LLGP may be different from half the length of the tip (LST). By the above described adjustment, a scooting of the foot may be avoided.

As another way to describe this, the groove 104 in bonding direction (in a longitudinal direction or length direction, also referred to as x-axis) may be constructed by at least one spline, which means that piecewise polynomial curves merge horizontally in the deepest point (the apex or apical point 104AP) of the groove 104. The contact point can be adjusted so that it is in a center of the force transmission, regardless of the shank 102 design. This may avoid moments, which may reduce scooting during the wire bonding process.

The contact point may be positioned symmetrically or asymmetrically to the shank 102 in the groove 104 region along the x-axis.

In the front region, the spline may merge tangentially into the shaft to create a smooth transition of the bonding wire 110 from the groove 104 into the loop.

In the back region, the end point of the spline may be parallel to the wire feeder 330. The plastic deformation of the bonding wire 110 in the heel area may therefore be minimized.

In various embodiments, a shape of the groove 104 along its width direction as defined by the jaws 102J is parabolic, ellipsoid or hyperbolic.

In other words, the shape of the groove 104 that shows up in a cross-section across a width of the groove 104 may be parabolic, ellipsoid or hyperbolic. This may be the case for any cross-section across a width of the groove 104, and thus along an entire length of the groove 104.

In various embodiments, for the bonding wire 110 having a predetermined diameter, for example a diameter between about 75 μm and about 500 μm, for example between 200 μm and about 400 μm, parameters of the parabola, the ellipse or the hyperbola may adjusted such that the groove 104 only partially accommodates the bonding wire 110, such that fractions of the bonding wire 110 diameter may be located outside the groove 104 when the groove 104 accommodates the bonding wire 110, for example a fraction of the bonding wire 110 as specified above, for example between about 40 % and about 60 %, for example about 50 % of the wire diameter.

In various embodiments, a material of the bonding wire 110 may be relevant for a desired shape of the groove 104. For example, for bonding wire 110 materials that cause adhesive wear (e.g. aluminum), an hyperbolic shape may be better to prevent material build up damaging the wedge of the bonding wire 110. Bonding materials with abrasive wear behaviour (e.g. copper) may instead benefit from a higher contact area and therefore more circular shape of the groove 104.

Thus, the shape of the parabola, the ellipse or the hyperbola may be determined taking into account the diameter and/or a material of the bonding wire 110. The definition of the shape of the groove 104 (across its width) as a conic shape (a conic section, e.g., a parabola, an ellipse (optionally excluding a circle), or a hyperbola) may make adjustments relatively easy.

In various embodiments, the parameters of the conic section, e.g., the parabola, the ellipse, or the hyperbola, may include a depth HG of the groove 104, a width WG of the groove 104, and a height of conic tangents HCT (see for example the cross-section at the right of FIG. 2 for an illustration of how the conic tangents are defined), or optionally, as an alternative to the height of conic tangents HCT, a curvature value κ.

In various embodiments, the conical, e.g., parabolic, groove 104 may be varied from a half-ellipse, e.g., a half circle, to an almost v-shape depending on parameters.

Parameter ranges for defining the spline curve along the length of the groove 104 and for defining the conical shape of the groove 104 across its width may be adapted to the wire 110 that is to be bonded using the wire bonding tool, for example to its diameter and material, and may include the following:

The height (or depth) HG of the groove 104 may for example be in a range from about 25 % to about 50 % of the wire diamenter.

The releasing end height HSF and/or the receiving end height HSB may be in a range from about 25 % to about 50 % of the wire diamenter.

A groove 104 width WG may be at least as large als the wire diamenter, but smaller than a width of the tip.

Various examples will be illustrated in the following:

Example 1 is a wire bonding tool. The wire bonding tool includes a groove for accommodating a bonding wire, and a pair of jaws defining side walls of the groove, wherein each jaw of the pair of jaws has a tip surface configured to face a bonding surface during operation, and wherein the tip surface of each jaw is curved.

In Example 2, the subject-matter of Example 1 may optionally include that the tip surface of each jaw is curved along its entire length.

In Example 3, the subject-matter of Example 1 or 2 may optionally include that the tip surface of each jaw has a convex shape in a length direction of the jaw.

In Example 4, the subject-matter of any of Examples 1 to 3 may optionally include that the tip surface of each jaw has a convex shape, a concave shape, or a flat shape in a width direction of the jaw.

In Example 5, the subject-matter of any of Examples 1 to 4 may optionally include that the curve of the tip surface of each jaw is defined as at least one spline, optionally a plurality of splines.

In Example 6, the subject-matter of any of Examples 1 to 5 may optionally include that a cross section of the foot portion orthogonal to a longitudinal axis of the shank is longer in a length direction of the groove than in a width direction of the groove orthogonal to the length direction of the groove, or that the cross section is quadratic.

Example 7 is a wire bonding tool. The wire bonding tool includes a groove for accommodating a bonding wire, wherein a shape of an apical line of the groove is a continuous convex curve defined by at least one spline, optionally a plurality of splines.

In Example 8, the subject-matter of Example 7 may optionally further include that the groove includes a receiving end configured to receive the bonding wire and a releasing end configured to release the bonding wire, and wherein, at the receiving end, an angle between a tangential to the apical line of the groove and a vertical forms an acute angle.

In Example 9, the subject-matter of Example 8 may optionally include that the acute angle matches a feeding angle at which the bonding wire is provided to the receiving end by a bonding wire feeder.

In Example 9a, the subject-matter of Example 7 may optionally further include that the groove includes a receiving end configured to receive the bonding wire and a releasing end configured to release the bonding wire, and wherein, at the receiving end, an angle between a tangential to the apical line of the groove and a vertical forms an angle, wherein, optionally, the wire bonding tool may further include a shank, and the angle may be tangential to an adjoining surface of the shank.

In Example 10, the subject-matter of Example 8, 9 or 9a may optionally include that, at the releasing end, the apical line of the groove is tangential to an adjoining surface of the shank.

In Example 10a, the subject-matter of Example 8, 9 or 9a may optionally include that, at the releasing end, the apical line of the groove is forms an angle with an adjoining surface of the shank (as opposed to being tangential to the adjoining surface of the shank).

In Example 11, the subject-matter of any of Examples 7 to 10 may optionally further include a pair of jaws defining side walls of the groove, wherein each jaw of the pair of jaws has a tip surface configured to face the bonding surface during operation, and wherein a curve of a tip surface of each jaw is essentially parallel to the apical line of the groove.

In Example 12, the subject-matter of any of Examples 7 to 11 may optionally include that parameters defining the at least one spline include at least one of a group of parameters, the group including or consisting of: a height of the groove (Height Groove, HG) defined as a distance, in a cross section across a width of the groove through a center of the groove, between a tip surface of the jaws and an apex of the groove, a receiving end height (Height Spline Back, HSB) defined as a distance between the apex point of the groove at the receiving end and at the center of the groove, a releasing end height (Height Spline Front, HSF) defined as a distance between the apex point of the groove at the releasing end and at the center of the groove, an angle (Angle Spline Back, ASB) of the apical line with respect to vertical at the receiving end, and an angle (Angle Spline Front, ASF) of the apical line with respect to vertical at the releasing end.

In Example 13, the subject-matter of Example 12 may optionally include that the receiving end height is equal to the releasing end height, or that the receiving end height is different from the releasing end height, wherein the receiving end height is larger than the releasing end height, or vice versa.

In Example 14, the subject-matter of any of Examples 7 to 13 may optionally include that a contact portion of the bonding wire with a bonding surface is located underneath an area of the foot portion where the apical line is closest to the bonding surface.

In Example 15, the subject-matter of Example 14 may optionally include that the apical line is configured to position the contact portion underneath a foot portion of a force vector for applying a bonding force.

Example 16 is a wire bonding tool. The wire bonding tool includes a groove for accommodating a bonding wire, and a pair of jaws defining side walls of the groove, wherein a shape of the groove along its width direction as defined by the jaws is a conic section, for example parabolic, ellipsoid or hyperbolic.

In Example 17, the subject-matter of Example 16 may optionally include that, for the bonding wire having a predetermined diameter, parameters of the parabola, the ellipse or the hyperbola are adjusted such that the groove only partially accommodates the bonding wire.

In Example 18, the subject-matter of Example 16 or 17 may optionally include that the parameters of the conic section, e.g., of the parabola, the ellipse or the hyperbola, include a depth of the groove, a width of the groove, and a height of conic tangents HCT (or, alternatively, a curvature value κ), which may be defined by a dedicated CAD model.

In Example 19, the subject-matter of any of Examples 16 to 18 may optionally include that the shape of the conic section, e.g., the parabola, the ellipse or the hyperbola, is determined taking into account a diameter and/or a material of the bonding wire.

Example 20 is a wire bonding tool. The wire bonding tool includes a shank, and a groove for accommodating a bonding wire formed at one end of the shank, wherein the groove includes a receiving end configured to receive the bonding wire and a releasing end configured to release the bonding wire, and wherein, at the receiving end, a tangential to an apical line of the groove and a surface of the shank to form an acute angle.

In Example 21, the subject-matter of Example 20 may optionally include that the acute angle matches a feeding angle at which the bonding wire is provided to the receiving end by a bonding wire feeder.

In Example 22, the subject-matter of Example 20 or 21 may optionally include that, at the releasing end, the apical line of the groove is tangential to an adjoining surface of the shank.

In Example 22a, the subject-matter of Example 20 or 21 may optionally include that, at the releasing end, the apical line of the groove forms an acute angle with an adjoining surface of the shank and/or an acute angle with respect to a vertical line.

Example 23 is a wire bonding tool. The wire bonding tool includes a shank and a groove for accommodating a bonding wire formed at one end of the shank, wherein the groove comprises a receiving end configured to receive the bonding wire and a releasing end configured to release the bonding wire, and wherein, at the releasing end, an apical line of the groove is tangential to an adjoining surface of the shank.

Any of Examples 1 to 6 may be combined with the feature(s) of one or more of Examples 7 to 23.

Any of Examples 7 to 15 may be combined with the feature(s) of one or more of Examples 1 to 6 and 16 to 23.

Any of Examples 16 to 19 may be combined with the feature(s) of one or more of Examples 1 to 15 and 20 to 23.

Any of Examples 20 to 22 may be combined with the feature(s) of one or more of Examples 1 to 19 and 23.

Example 23 may be combined with the feature(s) of one or more of Examples 1 to 22.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A wire bonding tool comprising:
a groove for accommodating a bonding wire; and
a pair of jaws defining side walls of the groove;
wherein each jaw of the pair of jaws has a tip surface configured to face a bonding surface during operation; and
wherein the tip surface of each jaw is curved.

2. The wire bonding tool of claim 1,
wherein the tip surface of each jaw is curved along its entire length.

3. The wire bonding tool of claim 1,
wherein the tip surface of each jaw has a convex shape in a length direction of the jaw.

4. The wire bonding tool of claim 1,
wherein a cross section of the foot portion orthogonal to a longitudinal axis of the shank is longer in a length direction of the groove than in a width direction of the groove orthogonal to the length direction of the groove, or the cross section is quadratic.

5. A wire bonding tool comprising:
a groove for accommodating a bonding wire;
wherein a shape of an apical line of the groove is a continuous convex curve defined by at least one spline.

6. The wire bonding tool of claim 5, further comprising:
a shank;
wherein the groove is formed at one end of the shank;
wherein the groove comprises a receiving end configured to receive the bonding wire and a releasing end configured to release the bonding wire; and
wherein, at the receiving end, an angle between a tangential to the apical line of the groove and a surface of the shank forms an acute angle.

7. The wire bonding tool of claim 6,
wherein the acute angle matches a feeding angle at which the bonding wire is provided to the receiving end by a bonding wire feeder.

8. The wire bonding tool of claim 6,
wherein, at the releasing end, the apical line of the groove is tangential to an adjoining surface of the shank.

9. The wire bonding tool of claim 5,
wherein parameters defining the at least one spline include at least one of a group of parameters, the group including or consisting of:
a height of the groove defined as a distance, in a cross section across a width of the groove through a center of the groove, between a tip surface of the jaws and an apex of the groove;
a receiving end height defined as a distance between the apex point of the groove at the receiving end and at the center of the groove;
a releasing end height defined as a distance between the apex point of the groove at the releasing end and at the center of the groove;
an angle of the apical line at the receiving end; and
an angle of the apical line at the releasing end.

10. The wire bonding tool of claim 9,
wherein the receiving end height is equal to the releasing end height; or
wherein the receiving end height is different from the releasing end height, wherein the receiving end height is larger than the releasing end height, or vice versa.

11. A wire bonding tool comprising:
a groove for accommodating a bonding wire; and
a pair of jaws defining side walls of the groove;
wherein a shape of the groove along its width direction as defined by the jaws is a conic section, optionally parabolic, ellipsoid or hyperbolic.

12. The wire bonding tool of claim 11,
wherein, for the bonding wire having a predetermined diameter, parameters of the conic section are adjusted such that the groove only partially accommodates the bonding wire.

13. The wire bonding tool of claim 11,
wherein the parameters of the conic section include a depth of the groove, a width of the groove, and a height of conic tangents.

14. A wire bonding tool comprising:
a shank; and
a groove for accommodating a bonding wire formed at one end of the shank;
wherein the groove comprises a receiving end configured to receive the bonding wire and a releasing end configured to release the bonding wire; and
wherein, at the receiving end, a tangential to an apical line of the groove and a vertical line form an acute angle.

15. A wire bonding tool comprising:
a shank;
a groove for accommodating a bonding wire formed at one end of the shank;
wherein the groove comprises a receiving end configured to receive the bonding wire and a releasing end configured to release the bonding wire; and
wherein, at the releasing end, an apical line of the groove is tangential to an adjoining surface of the shank.

16. A method of forming a wire bond, the method comprising:
attaching a bonding wire to a bonding surface using the wire bonding tool of claim 1.
